(19) United States
(12) Patent Application Publication
(10) Pub. No.: US 2016/0268501 A1
(43) Pub. Date: Sep. 15, 2016

(54) MAGNETIC MEMORY DEVICE

(71) Applicant: KABUSHIKI KAISHA TOSHIBA, Tokyo (JP)

(72) Inventor: Eiji KITAGAWA, Yokohama Kanagawa (JP)

(73) Assignee: KABUSHIKI KAISHA TOSHIBA, Tokyo (JP)

(21) Appl. No.: 14/848,275

(22) Filed: Sep. 8, 2015

Related U.S. Application Data
(60) Provisional application No. 62/132,323, filed on Mar. 12, 2015.

(51) Int. Cl. H01L 43/08; H01L 27/22; H01L 43/10

(52) U.S. Cl. CPC H01L 43/08; H01L 43/10; H01L 27/222

(57) ABSTRACT

According to one embodiment, a magnetic memory device includes a magnetoresistive effect element including a first magnetic layer in which a first layer containing Co, Fe and B and a second layer containing Co, Fe and a predetermined element selected from Tb, Dy and Gd are stacked, a second magnetic layer, and a nonmagnetic layer between the first magnetic layer and the second magnetic layer. The magnetoresistive effect element is set to low-resistance and high-resistance states by applying first and second voltages respectively to allow current to flow from the first magnetic layer to the second magnetic layer, and one of the low-resistance and high-resistance states is read by applying a third voltage to allow current to flow from the second magnetic layer to the first magnetic layer.

### CROSS-REFERENCE TO RELATED APPLICATIONS

This application claims the benefit of U.S. Provisional Application No. 62/132,323, filed Mar. 12, 2015, the entire contents of which are incorporated herein by reference.

### FIELD

Embodiments described herein relate generally to a magnetic memory device.

### BACKGROUND

Magnetic memory devices (semiconductor integrated circuit devices) comprising a magnetoresistive effect element and transistors are integrated on a semiconductor substrate have been proposed.

The magnetic memory devices described above carry out a write operation by allowing a current through the magnetoresistive effect element, and a read operation by allowing a current smaller than the current of the write operation through the magnetoresistive effect element.

In the magnetic memory devices described above, currents are allowed to flow through the magnetoresistive effect element in both the write and read operations, and therefore there is a possibility of erroneously writing at the time of reading.

Under these circumstances, there is a demand for a magnetic memory device which can prevent erroneously writing at the time of read operation.

### BRIEF DESCRIPTION OF THE DRAWINGS

FIG. 1 is a cross-sectional view schematically showing the structure of a magnetic memory device (semiconductor integrated circuit device) which employs a magnetoresistive effect element according to an embodiment.

FIG. 2 is an equivalent circuit diagram showing the structure of the magnetic memory device (semiconductor integrated circuit device) which employs the magnetoresistive effect element according to the embodiment.

FIG. 3 is a cross-sectional view schematically showing the structure of a reference layer, a storage layer and a tunnel barrier layer contained in the magnetoresistive effect element according to the embodiment.

FIG. 4 is a diagram showing the relationship between the Tb concentration of a TbCoFe layer and the MR ratio.

FIG. 5 is a diagram showing the verification result of the write operation of the magnetoresistive effect element according to the embodiment.

FIG. 6 is a diagram schematically showing the structure of a magnetoresistive effect element according to a modified example of the embodiment.

FIG. 7 is a magnetic phase diagram of a case where the structure of the modified example of the embodiment is used.

FIG. 8 is a diagram showing a result of the characteristics shown in FIG. 7 estimated by a macro-spin model.

FIG. 9 is a diagram showing a result of the characteristics shown in FIG. 7 estimated by a macro-spin model.

FIG. 10 is a magnetic phase diagram of a case where the structure of the embodiment is used.

FIG. 11 is a cross-sectional view schematically showing the structure of a reference layer, a storage layer, a tunnel barrier layer and an under layer contained in the magnetoresistive effect element according to the embodiment.

FIG. 12 is a magnetic phase diagram of a case where the structure of the modified example of the embodiment is used.

FIG. 13 is a cross-sectional view schematically showing the structure of a storage layer contained in the magnetoresistive effect element according to the embodiment.

### DETAILED DESCRIPTION

In general, according to one embodiment, a magnetic memory device includes a magnetoresistive effect element including a first magnetic layer in which a first layer containing Co, Fe and B and a second layer containing Co, Fe and a predetermined element selected from Tb, Dy and Gd are stacked; a second magnetic layer; and a nonmagnetic layer between the first magnetic layer and the second magnetic layer, the first layer being located between the second layer and the nonmagnetic layer, wherein the magnetoresistive effect element is set to a low-resistance state by applying a first voltage to the magnetoresistive effect element to allow current to flow from the first magnetic layer to the second magnetic layer, the magnetoresistive effect element is set to a high-resistance state having a resistance higher than that of the low-resistance state by applying a second voltage lower than the first voltage to the magnetoresistive effect element to allow current to flow from the first magnetic layer to the second magnetic layer, and one of the low-resistance state and the high-resistance state is read from the magnetoresistive effect element by applying a third voltage to the magnetoresistive effect element to allow current to flow from the second magnetic layer to the first magnetic layer.

An embodiment will now be described with reference to drawings.

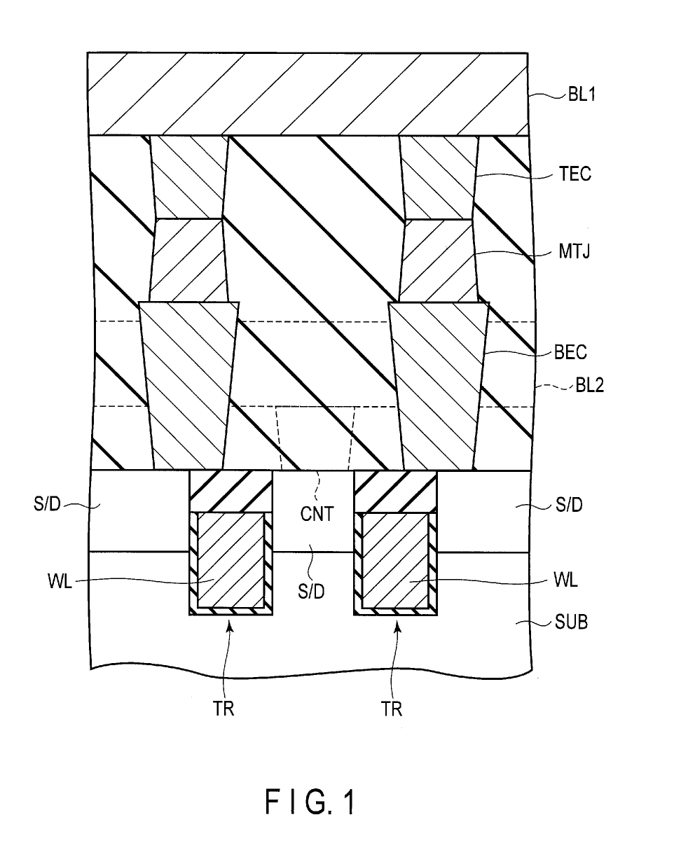

FIG. 1 is a cross-sectional view schematically showing the structure of a magnetic memory device (semiconductor integrated circuit device) which employs a magnetoresistive effect element (magnetic tunnel junction [MTJ] element) according to an embodiment.

As shown in FIG. 1, a MOS transistor TR of a buried gate type is formed in a semiconductor substrate SUB. The gate electrode of the MOS transistor TR is used as a word line WL. A bottom electrode BEC is connected to one of the source/drain regions S/D of the MOS transistor TR and a contact CNT is connected to the other one of the source/drain regions S/D.

The magnetoresistive effect element MTJ is formed on the bottom electrode BEC and the top electrode TEC is formed on the magnetoresistive effect element MTJ. A first bit line BL1 is connected to the top electrode TEC. A second bit line BL2 is connected to the contact CNT.

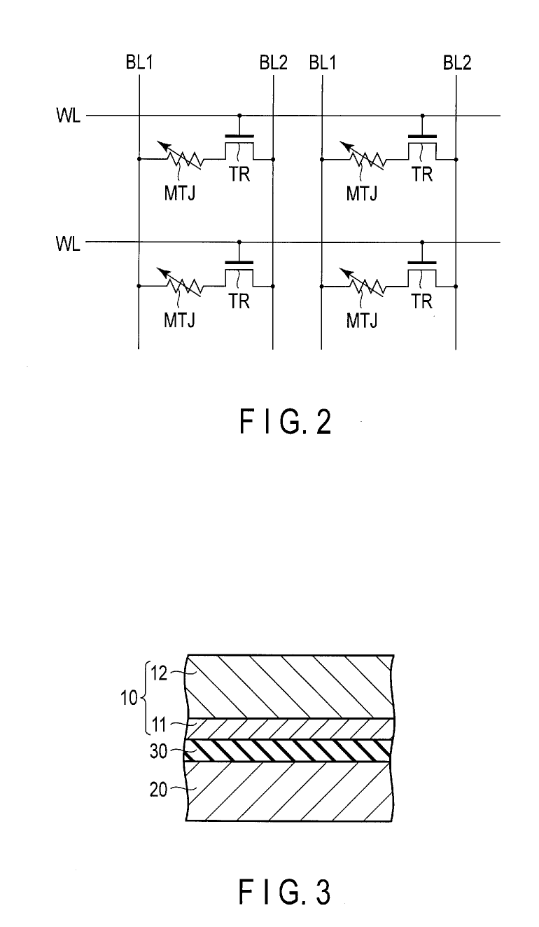

FIG. 2 is an equivalent circuit diagram showing the structure of the magnetic memory device (semiconductor integrated circuit device) which employs the magnetoresistive effect element of this embodiment.

As shown in FIG. 2, series circuit units each comprising the magnetoresistive effect element MTJ and the MOS transistor TR are arranged in an array manner. A first bit line BL1 is connected to one end of each of the series circuit units and a second bit line BL2 is connected to the other end of each of the series circuit units. A word line WL is connected to the gate electrode of the magnetoresistive effect element MTJ.

FIG. 3 is a sectional view schematically showing the structure of a reference layer, a storage layer and a tunnel barrier layer contained in the magnetoresistive effect element MTJ.

As shown in FIG. 3, the magnetoresistive effect element comprises a reference layer (first magnetic layer) 10, a storage memory layer (second magnetic layer) 20, a tunnel barrier layer (nonmagnetic layer) 30 located between the reference layer (first magnetic layer) 10 and the storage layer (second magnetic layer) 20.

The reference layer (first magnetic layer) 10 has a structure in which a first layer 11 and a second layer 12 are stacked. As shown in FIG. 3, the first layer 11 is located between the second layer 12 and the nonmagnetic layer 30. The first layer 11 contains Co, Fe and B. Specifically, the first layer 11 is a CoFeB layer. The second layer 12 contains Co and Fe and a predetermined element selected from Tb, Dy and Gd. Specifically, the second layer 12 is a TbCoFe layer, a DyCoFe layer or a GdCoFe layer. In this embodiment, a TbCoFe layer is used as the second layer 12.

The storage layer (second magnetic layer) 20 contains Co, Fe and B. Specifically, the storage layer 20 is a CoFeB layer.

The tunnel barrier layer (nonmagnetic layer) 30 contains Mg and O. Specifically, the tunnel barrier layer 30 is a MgO layer.

The reference layer 10 and the storage layer 20 both have magnetization of the perpendicular direction. The magnetization direction of the reference layer 10 is fixed. That is, the first layer 11 and the second layer 12 both have fixed magnetization directions. Further, the magnetization direction of the second layer 12 is antiparallel to the magnetization direction of the first layer 11.

The magnetization direction of the storage layer 20 is variable.

The magnetoresistive effect element of this embodiment is in a low-resistance state when the magnetization direction of the storage layer 20 is parallel to the magnetization direction of the first layer 11 of the reference layer 10, and in a high-resistance state when the magnetization directions of the storage layer 20 is anti-parallel to the magnetization direction of the first layer 11 of the reference layer 10. Based on the low- and high-resistance states, desired data (binary 0 or 1) can be stored.

In the magnetoresistive effect element of this embodiment, the write operation is performed by allowing a current to flow to the storage layer (second magnetic layer) 20 from the reference layer (first magnetic layer) 10. More specifically, when the first voltage V1 is applied to the magnetoresistive effect element to allow a current to flow to the storage layer 20 from the reference layer 10, the magnetoresistive effect element is set in the low-resistance state. Further, when the second voltage V2 lower than the first voltage V1 is applied to the magnetoresistive effect element to allow a current flow to the storage layer 20 from the reference layer 10, the magnetoresistive effect element is set in the high-resistance state, which has a resistance higher than that of the low-resistance state.

Meanwhile, in the magnetoresistive effect element of this embodiment, the read operation is performed by allowing a current to flow from the storage layer (second magnetic layer) 20 to the reference layer (first magnetic layer) 10. More specifically, when the third voltage V3 is applied to the magnetoresistive effect element to allow a current to flow to the reference layer 10 from the storage layer 20, one of the low- and high-resistance states is read from the magnetoresistive effect element. Note that the current flowing to the reference layer 10 from the storage layer 20 when applying the third voltage V3 to the magnetoresistive effect element is greater than or equal to the above-described current flowing to the storage layer 20 from the reference layer 10 when applying the second above-mentioned voltage V2. Further, the above-provided description is directed to the case where the write operation is performed by applying voltage, but alternatively, the write operation can also be performed by delivering current instead of applying voltage. In other words, the write operation can be similarly performed by substituting the first voltage described above by the first current, the second voltage by the second current, and the third voltage by the third current, and setting the second current smaller than the first current and the third current larger than the second current.

In a normal magnetoresistive effect element, the write direction (current direction) to set a low-resistance state and the write direction (current direction) to set a high-resistance state are opposite to each other. Therefore, in some cases, the read direction (current flow direction) for performing the read operation and the write direction (current direction) for performing the write operation become the same. In these cases, there is a possibility of erroneously performing a write when a read operation should be performed. Usually, measures are taken to prevent such a write error by setting the read current sufficiently lower than the write current. However, when the read current is excessive low, it is difficult to differentiate a low-resistance state and a high-resistance state.

In the magnetoresistive effect element of this embodiment, the direction of the write current to set the low-resistance state and the direction of the write current to set the high-resistance state are the same, and the direction of the write current and the direction of the read current are opposite to each other. With this configuration, even if the read voltage is made high to increase the read current, the write error can be prevented. Thus, the third voltage V3 can be set greater than or equal to the second voltage V2.

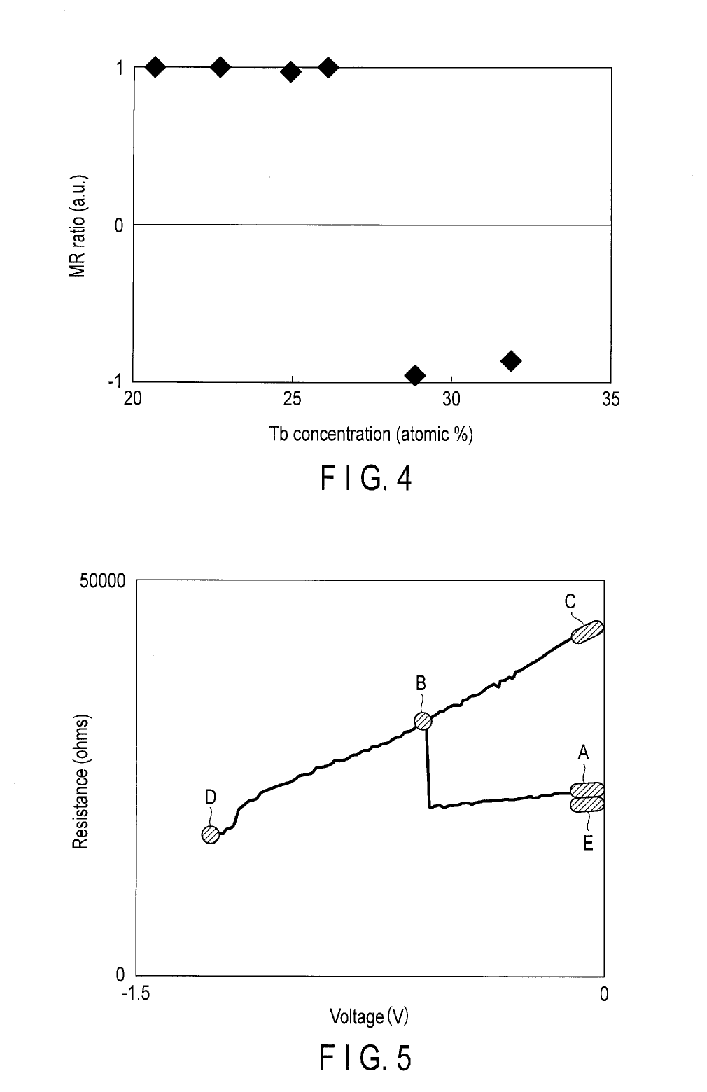

FIG. 4 shows the relationship between Tb concentration (Tb composition) of the second layer (TbCoFe layer) 12 and the MR ratio. For measurement, the MTJ film used in FIG. 3 was used, and the MR ratio was evaluated by CIPT measurement.

When the Tb concentration is lower than 27 atomic %, a positive MR ratio is obtained because the magnetization of the first layer (CoFeB layer) 11 is greater than that of the second layer (TbCoFe layer) 12. When the Tb concentration is greater than or equal to 27 atomic %, the magnetization of the TbCoFe layer becomes greater than that of the CoFeB layer and therefore a negative MR ratio is obtained. When a negative MR ratio is obtained, it is easy to perform a write operation of one direction such as mentioned above. Therefore, the second layer (TbCoFe layer) 12 should preferably contain 27 atomic % or more of Tb.

For the CoFeB layer of the first layer 11, it is desirable to use a CoFeB material containing Co a main ingredient, whose Co content is higher than the Fe content and B content. With this composition, it is easy to perform the write operation of one direction described above.

FIG. 5 shows the results obtained in a verification of the write operation of one direction described above. The Tb concentration of the second layer (TbCoFe layer) 12 was set to 29 atomic % with respect to the contents of Co and Fe. Further, the Co concentration of the first layer (CoFeB layer) 11 was set to 60 atomic % with respect to the contents of Fe and B. Furthermore, a Ta layer (0.3 nm) so thin as not to lose the magnetic coupling was inserted to the first layer 11 in order to increase the MR ratio. The one-directional writing is possible if no Ta layer is inserted, but with a Ta layer inserted, the MR ratio rises and therefore the read becomes easy. For this reason, it is preferable to insert a high melting-point transition metal layer such as Ta layer in the first layer 11 as a functional layer. The direction of the voltage applied to the magnetoresistive effect element is direction of flow of current from the reference layer 10 to the storage layer 20. The voltages are applied in the order of A B, C, D and E shown in FIG. 5.

First, a voltage of 100 mV (A) was applied to the magnetoresistive effect element and it was confirmed that the magnetoresistive effect element is in the low-resistance states. Then, a voltage of 600 mV (B) was applied to the magnetoresistive effect element and the magnetoresistive effect element transitioned from the low- to high-resistance state. Subsequently, a voltage of 100 mV (C) was applied to the magnetoresistive effect element, and it was confirmed that the magnetoresistive effect element was in the high-resistance state. Then, a voltage of 1200 mV (D) was applied to the magnetoresistive effect element and the magnetoresistive effect element transitioned from the high- to low-resistance state. Further, a voltage of 100 mV (E) was applied to the magnetoresistive effect element, and it was confirmed that the magnetoresistive effect element was in the low-resistance state.

As can be seen in FIG. 5, with the magnetoresistive effect element of this embodiment, it is possible, by changing the magnitude of the applied voltage, to perform writes in both the low- and high-resistance states even if the directions of write currents are the same.

As described above, in this embodiment, the reference layer (first magnetic layer) 10 is formed to have a multilayered structure comprising the first layer 11 containing Co, Fe and B and the second layer 12 containing Tb (or Dy or Gd), Co and Fe. With this structure, it is possible to perform write operations in both the low- and high-resistance states in the same write current direction. Therefore, the directions of the read and write currents can be made opposite to each other at all times. For this reason, even if the read voltage is raised high (even if the read current is increased), write errors can be prevented, making it possible to obtain a high-performance magnetic memory device.

Moreover, with this embodiment, the read voltage can be raised high, which enables a high-speed read operation. When the read time is 10 ns or less, or if the read time becomes less than or equal to the incubation time, the magnetization reversal current will increase rapidly. As a result, the probability of the write error by the read current can be decreased sharply.

Moreover, with this embodiment, it is not necessary to lower the read voltage, and therefore a voltage-down circuit is not required. Therefore, the circuits can be simplified and the scale of circuit can be reduced.

Additionally, when the storage layer (second magnetic layer) 20 is formed from a CoFeB layer, the following problem may arise. That is, if a read directional voltage is applied to the magnetoresistive effect element, or a voltage is applied in a direction which allows a current to flow from the storage layer 20 to the reference layer 10, a spin torque of the direction in which the magnetoresistive effect element transitions to the low-resistance state is applied to the storage layer 20. As a result, when a read operation is performed while the magnetoresistive effect element is in the high-resistance state, a write error may occur.

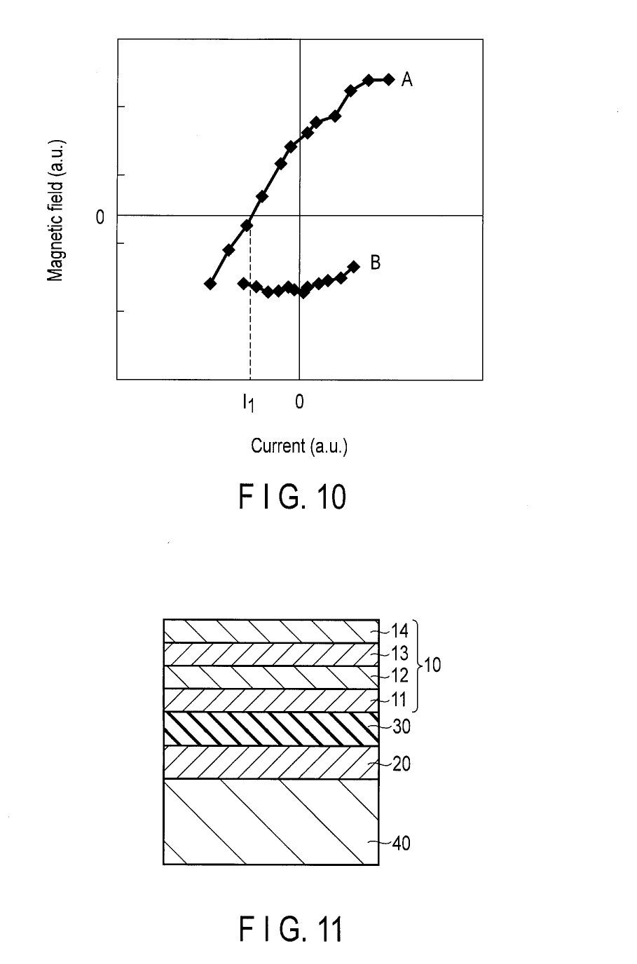

In order to avoid this, the concentration of Tb is set to 35% or higher to increase the magnetic field which leaks from the second layer 12 to the storage layer 20 shown in FIG. 3. Or as shown in FIG. 11, a Ru layer is stacked as the third layer 13 on the second layer 12 and a CoPt layer is stacked as the fourth layer 14 on the third layer 13 so as to set the magnetization direction of the second layer 12 and the fourth layer 14 in the same direction. Then, a magnetic field larger than the magnetic field leaking from the first layer 11 to the storage layer 20 is applied from the second layer 12 and the fourth layer 14 so as to set a leaking magnetic field which stabilizes when the magnetizations of the two magnetic layers sandwiching the tunnel barrier layer 30 are anti-parallel to each other. When the shift magnetic field is adjusted in a uniform magnetic field, a magnetic phase diagram as shown in FIG. 10 is obtained.

A state where the magnetization of the storage layer 20 and the magnetization of the reference layer 10 are anti-parallel on the left-hand side of line A in FIG. 10 is stabilized, and a state where the magnetization of the storage layer 20 and the magnetization of the reference layer 10 are parallel to each other below line B is stabilized. The negative direction of the horizontal axis of FIG. 10 indicates the direction in which current flows from the reference layer 10 to the storage layer 20. For example, if current is allowed to flow in the negative direction and a current value exceeds I1, data is written from the low- to high-resistance state.

The positive direction of the horizontal axis indicates the direction in which current flows from the storage layer 20 to the reference layer 10. Here, line B does not intersect the zero magnetic field, the write current for shifting from the high- to low-resistance state increases drastically, making it difficult to perform a write operation. For this reason, the write error while applying a voltage of a read direction is inhibited. Note that the uniform magnetic field used to adjust the shift magnetic field can be realized by attaching a magnetic member on one side of a memory device (shift magnetic field adjustment layer). Further, when the shift magnetic field is sufficiently smaller than the magnetization reversal magnetic field of the storage layer, the adjustment of the shift magnetic field by the uniform magnetic field is not required.

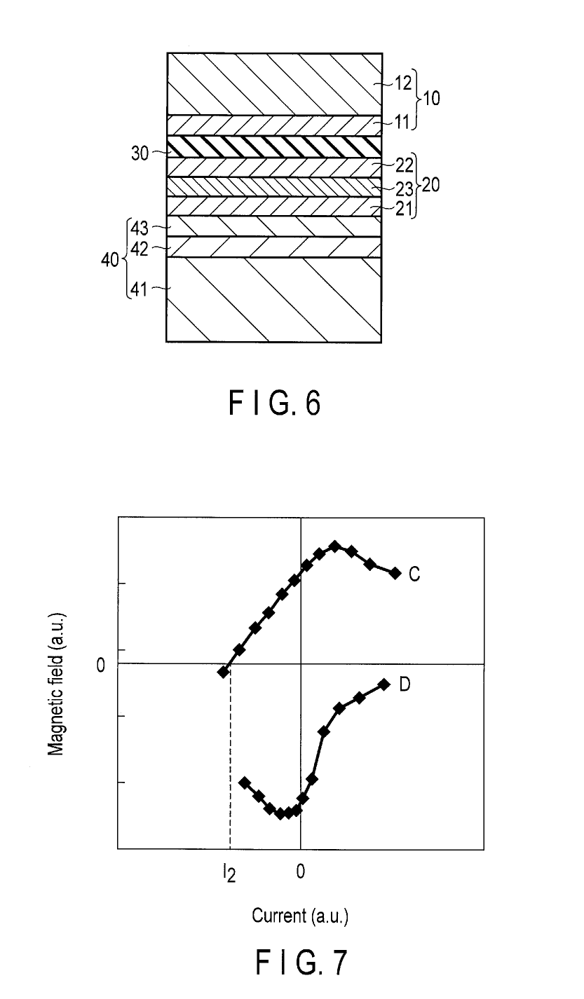

FIG. 6 schematically shows the structure of a modified example of the magnetoresistive effect element for preventing such a problem described above.

In the magnetoresistive effect element shown in FIG. 6, the storage layer (second magnetic layer) 20 comprises a lower layer part 21 containing Co, Fe and B, an upper layer part 22 located between the nonmagnetic layer 30 and the lower layer part 21 and containing Co, Fe and B, and a middle layer part 23 located between the lower layer part 21 and the upper layer part 22 and containing Mg, Fe and O.

More specifically, the lower layer part 21 and the upper layer part 22 are both CoFeB layers and the middle layer part 23 is a MgFeO layer. The thickness of the lower layer part 21 and the upper layer part 22 is about 1.4 nm, and the thickness of the middle layer part 23 is about 0.9 nm. The middle layer part 23 is obtained by forming a MgFeO layer (0.3 nm in thickness), a MgO layer (0.3 nm in thickness) and a MgFeO layer (0.3 nm in thickness) sequentially. The thickness of each layer part is very thin, the middle layer part 23 is substantially a MgFeO layer. Note that the middle layer part (MgFeO layer) 23 should preferably contain 5 or more and 50 or less atomic % of Fe with respect to Mg. In the middle layer part (MgFeO layer) 23, it is possible to suppress the mismatching of lattice occurring between CoFeB and MgFeO when the concentration (content) of Fe is set to 50 atomic % or less with respect to that of Mg. Further, with use of MgFeO, the wettability to adjacent CoFeB can be improved, enabling to form a flat film. The MgO layer inserted between the MgFeO layers is used to promote crystallization of the middle layer part 23. With the crystallized middle layer part 23 thus formed, the spin torque can be propagated between the lower layer part 21 and the upper layer part 22. Furthermore, the MgFeO layers should preferably have a composition which is oxygen-deficient as compared to its stoichiometrical composition. With the deficiency in oxygen, the conductivity of the middle layer part 23 can be improved, enabling to suppress degradation in the MR ratio.

An under layer 40 is provided under the storage layer 20. The under layer 40 comprises a Sc—HfB layer 41, an AlScN layer 42 and an AlN layer 43.

FIG. 7 is a magnetic phase diagram showing the case where the structure of FIG. 6 is used. As shown in FIG. 7, the negative current direction is a write direction in which current is allowed to flow from the reference layer 10 to the storage layer 20. When a current I2, in which line C intersects the zero field, is allowed to flow, the magnetization states of the storage layer 20 and the reference layer 10 transition from the parallel to the anti-parallel state, enabling to write to the high-resistance state from the low resistance-state. On the other hand, the positive current direction is a read direction in which current is allowed to flow from the storage layer 20 to the reference layer 10. Here, since line D does not intersect the zero magnetic field, transition from the high- to low-resistance state can be prevented.

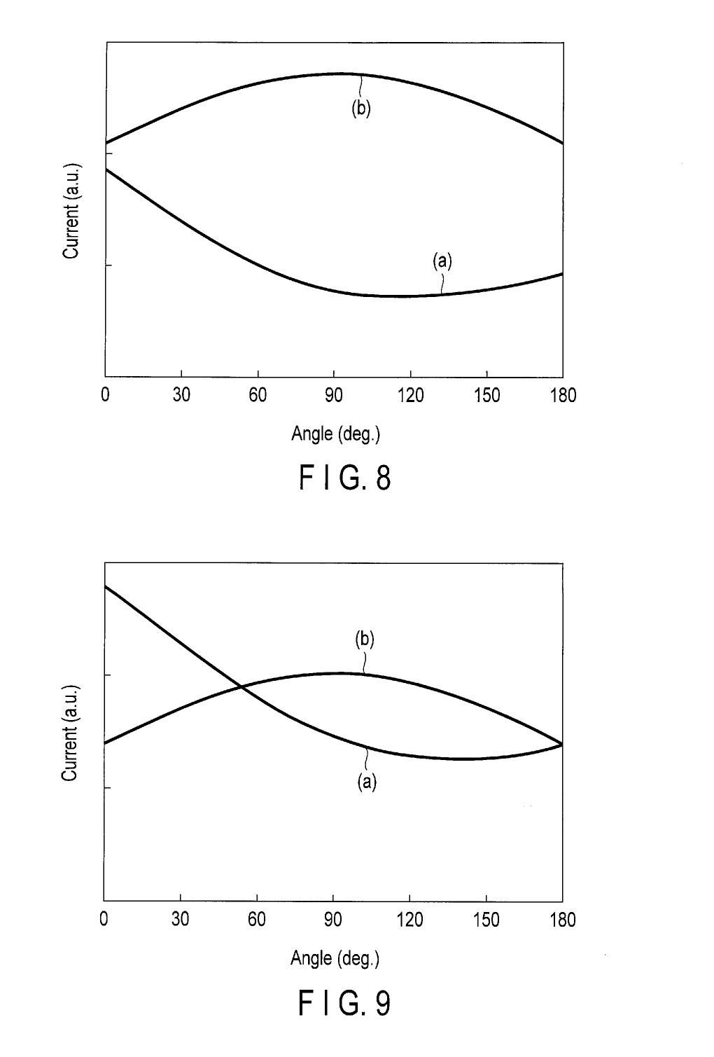

FIGS. 8 and 9 show results of estimation of the characteristics shown in FIG. 7 acquired by a macro spin model. The horizontal axis indicates a spin angle of the CoFeB layer (lower layer part 21) and the CoFeB layer (upper layer part 22), and the vertical axis indicates a critical reversal current Ico. In FIGS. 8 and 9, case (a) illustrates the characteristics of the lower layer part 21 and case (b) illustrates the characteristics of the upper layer part 22.

FIG. 8 shows characteristics when the thermal stability factor of the lower layer part 21 is lower than that of the upper layer part 22. More specifically, the characteristics shown here are obtained when the thermal stability factor of the lower layer part 21 is t40 and the thermal stability factor of the upper layer part 22 is A60. Here, the magnetization reversal current of case (a) is less than the magnetization reversal current of case (b). Therefore, the lower layer part 21 is reversed first. After that, the spin accumulation effect acting between the lower layer part 21 and the upper layer part 22 and the spin torque applied from the reference layer 10 to the upper layer part 22 interfere with each other so as to inhibit erroneous reversal which may be caused by the read current. It is estimated that as a result, the characteristics of line D in FIG. 7 are acquired.

FIG. 9 shows characteristics obtained when the thermal stability factor of the lower layer part 21 is higher than that of the upper layer part 22. More specifically, the characteristics shown here are obtained when the thermal stability factor of the lower layer part 21 is A60 and the thermal stability factor of the upper layer part 22 is Δ40. As shown in FIG. 9, in the case where the thermal stability factor of the lower layer part 21 is higher than that of the upper layer part 22, when the angle made by the spin of the lower layer part 21 and the spin of the upper layer part 22 is 60 degrees, the lower layer part 21 and the upper layer part 22 are simultaneously reversed and thus magnetization reversal by the read current occurs. Therefore, the prevention function of a reversal error by the read current is lost.

As can be understood from the above-provided description, it is important to appropriately design the thermal stability factors of the lower layer part 21 and the upper layer part 22 in order to prevent the reversal error by read current.

That is, it is preferable to set the thermal stability factor Δ1 of the lower layer part 21 smaller than the thermal stability factor 42 of the upper layer part 22.

For example, the thermal stability factor of the lower layer part 21 can be made lower than the thermal stability factor of the upper layer part 22 by making the B concentration of the lower layer part 21 higher than the B concentration of the upper layer part 22. More specifically, it is preferable to set the B concentration of the lower layer part 21 higher than 20 atomic % and to set the B concentration of the upper layer part 22 lower than 20 atomic %. Alternatively, the thermal stability factor of the lower layer part 21 can be made lower than the thermal stability factor of the upper layer part 22 by making the Fe concentration of the lower layer part 21 lower than the Fe concentration of the upper layer part 22. More specifically, it is preferable to set the Fe concentration of the lower layer part 21 lower than 90 atomic % with respect to the Co concentration and to set the Fe concentration of the upper layer part 22 higher than 90 atomic % with respect to the Co concentration. Alternatively, the thermal stability factor of the lower layer part 21 can be made lower than the thermal stability factor of the upper layer part 22 by making the thickness of the lower layer part 21 greater than that of the upper layer part 22.

As described above, this modified example is similar to the above-described embodiment in basic structure, and an advantageous effect similar to that of the above-described embodiment can be obtained in this modified example.

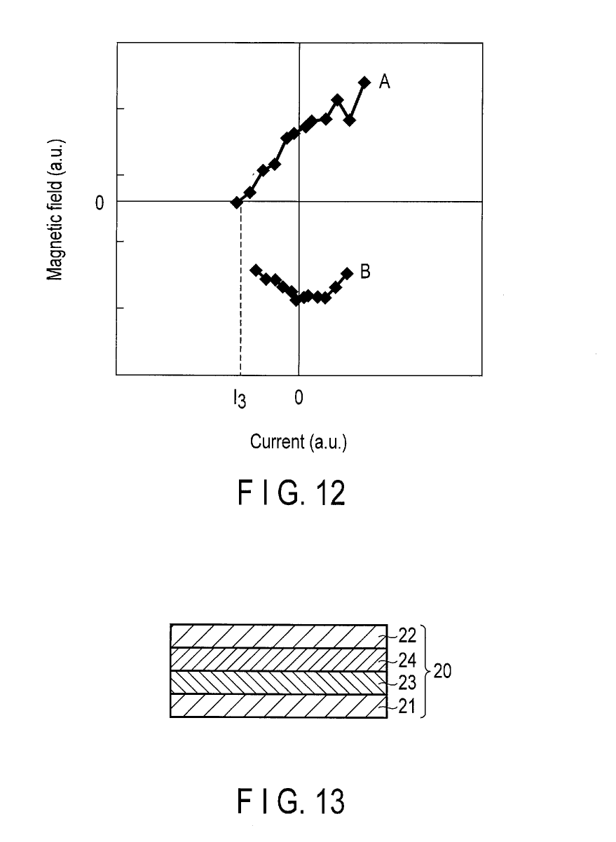

Moreover, in a modified example shown in FIG. 13, the storage layer (second magnetic layer) 20 comprises a lower layer part 21 containing Co, Fe and B, a upper layer part 22 containing Co, Fe and B, a first middle layer part 23 containing Mg, Fe and O and a second middle layer part 24 containing Al and N, which are located between the lower layer part 21 and the upper layer part 22. With this structure, the magnetic exchange coupling between the lower layer part 21 and the upper layer part 22 can be weakened. Therefore, the magnetic phase diagram shown in FIG. 12 is obtained. As to the write current of the negative current direction, it is possible to write when the current is I3. But with the read current of the positive current direction, even if the voltage is high (even if the read current is increased), the magnetization reversal is not performed. In this manner, write errors can be prevented and thus it is possible to obtain a high-performance magnetic memory device.

Note that in the embodiment and the modified examples described above, the storage layer (second magnetic layer) 20 may contain at least one element selected from Au, Pd, Pt, Rh and Ru. For example, the storage layer 20 may contain 10 atomic % or more of these elements. When such a transition metal having a great spin orbit interaction is added to the storage layer 20, a read disturb can be prevented. In this case, the perpendicular magnetic anisotropy of the storage layer 20 changes when the orbital moment varies with applied voltage. For example, the perpendicular magnetic anisotropy decreases in the write direction, and the perpendicular magnetic anisotropy increases in the read direction. With the increase in the perpendicular magnetic anisotropy, the thermal stability factor at the time of a read operation can be raised, enabling to prevent the write error at the time of the read operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising a magnetoresistive effect element comprising a first magnetic layer in which a first layer containing Co, Fe and B and a second layer containing Co, Fe and a predetermined element selected from Tb, Dy and Gd are stacked; a second magnetic layer; and a nonmagnetic layer between the first magnetic layer and the second magnetic layer, the first layer being located between the second layer and the nonmagnetic layer, wherein
the magnetoresistive effect element is set to a low-resistance state by applying a first voltage to the magnetoresistive effect element to allow current to flow from the first magnetic layer to the second magnetic layer,
the magnetoresistive effect element is set to a high-resistance state having a resistance higher than that of the low-resistance state by applying a second voltage lower than the first voltage to the magnetoresistive effect element to allow current to flow from the first magnetic layer to the second magnetic layer, and
one of the low-resistance state and the high-resistance state is read from the magnetoresistive effect element by applying a third voltage to the magnetoresistive effect element to allow current to flow from the second magnetic layer to the first magnetic layer.

2. The device of claim 1, wherein
the third voltage is greater than or equal to the second voltage.

3. The device of claim 1, wherein
the predetermined element is Tb, and a ratio of Tb contained in the second layer is 27 atomic % or more.

4. The device of claim 1, wherein
the second magnetic layer contains Co, Fe, and B.

5. The device of claim 1, wherein
the nonmagnetic layer contains Mg and O.

6. The device of claim 1, wherein
the first magnetic layer further comprises a third layer provided on the second layer and formed of Ru, and a fourth layer provided on the third layer and formed of CoPt, and a magnetization direction of the second layer and a magnetization direction of the fourth layer are parallel to each other.

7. The device of claim 1, wherein
the second magnetic layer includes a lower layer part containing Fe and B, an upper layer part between the nonmagnetic layer and the lower layer part and containing Fe and B, and a middle layer part between the lower layer part and the upper layer part and containing Mg, Fe and O.

8. The device of claim 7, wherein
a thermal stability factor Δ1 of the lower layer part is smaller than a thermal stability factor Δ2 of the upper layer part.

9. The device of claim 7, wherein
a B concentration of the lower layer part is higher than a B concentration of the upper layer part.

10. The device of claim 7, wherein
an Fe concentration of the lower layer part is lower than an Fe concentration of the upper layer part.

11. The device of claim 7, wherein
a thickness of the lower layer part is greater than a thickness of the upper layer part.

12. The device of claim 7, wherein
the middle layer part is a stacked layer of an AIN layer and an MgFeO layer.

13. The device of claim 1, wherein
the second magnetic layer contains at least one element selected from Au, Pd, Pt, Rh and Ru.

14. The device of claim 1, further comprising shift magnetic field adjustment layer in which a magnetic member is attached to one surface of a memory device, and
a ratio of Tb contained in the second layer is 35 atomic % or more.

15. A magnetic memory device comprising a magnetoresistive effect element comprising a first magnetic layer; a second magnetic layer; and a nonmagnetic layer between the first magnetic layer and the second magnetic layer, wherein
the second magnetic layer includes a lower layer part containing Fe and B, an upper layer part between the nonmagnetic layer and the lower layer part and containing Fe and B, and a middle layer part between the lower layer part and the upper layer part and containing Mg, Fe and O,
the magnetoresistive effect element is set to a low-resistance state by applying a first voltage to the magnetoresistive effect element to allow current to flow from the first magnetic layer to the second magnetic layer,
the magnetoresistive effect element is set to a high-resistance state having a resistance higher than that of the low-resistance state by applying a second voltage lower than the first voltage to the magnetoresistive effect element to allow current to flow from the first magnetic layer to the second magnetic layer, and
one of the low-resistance state and the high-resistance state is read from the magnetoresistive effect element by applying a third voltage to the magnetoresistive effect element to allow current to flow from the second magnetic layer to the first magnetic layer.

16. A magnetic memory device comprising a magnetoresistive effect element comprising a first magnetic layer in which a first layer containing Co, Fe and B and a second layer containing Co, Fe and a predetermined element selected from Tb, Dy and Gd are stacked; a second magnetic layer; and a nonmagnetic layer between the first magnetic layer and the second magnetic layer, the first layer being located between the second layer and the nonmagnetic layer, wherein
the second magnetic layer includes a lower layer part containing Fe and B, an upper layer part between the nonmagnetic layer and the lower layer part and containing Fe and B, and a middle layer part between the lower layer part and the upper layer part and containing Mg, Fe and O.

17. The device of claim 16, wherein
the predetermined element is Tb, and a ratio of Tb contained in the second layer is 27 atomic % or more.

18. The device of claim 16, wherein
a thermal stability factor Δ1 of the lower layer part is smaller than a thermal stability factor Δ2 of the upper layer part.

19. The device of claim 16, wherein
the second magnetic layer contains at least one element selected from Au, Pd, Pt, Rh and Ru.

20. A magnetic memory device comprising a magnetoresistive effect element comprising a first magnetic layer in which a first layer containing Co, Fe and B and a second layer containing Co, Fe and a predetermined element selected from Tb, Dy and Gd are stacked; a second magnetic layer; and a nonmagnetic layer between the first magnetic layer and the second magnetic layer, the first layer being located between the second layer and the nonmagnetic layer, wherein
the magnetoresistive effect element is set to a low-resistance state by applying a first current to the magnetoresistive effect element to allow current to flow from the first magnetic layer to the second magnetic layer,
the magnetoresistive effect element is set to a high-resistance state having a resistance higher than that of the low-resistance state by applying a second current lower than the first current to the magnetoresistive effect element to allow current to flow from the first magnetic layer to the second magnetic layer, and
one of the low-resistance state and the high-resistance state is read from the magnetoresistive effect element by applying a third current to the magnetoresistive effect element to allow current to flow from the second magnetic layer to the first magnetic layer.

21. A magnetic memory device comprising a magnetoresistive effect element comprising a first magnetic layer; a second magnetic layer; and a nonmagnetic layer between the first magnetic layer and the second magnetic layer, wherein
the second magnetic layer includes a lower layer part containing Fe and B, an upper layer part between the nonmagnetic layer and the lower layer part and containing Fe and B, and a middle layer part between the lower layer part and the upper layer part and containing Mg, Fe and O.
